(19) United States
(12) Patent Application Publication
(10) Pub. No.: US 2021/0194211 A1
(43) Pub. Date: Jun. 24, 2021

(54) SEMICONDUCTOR LASER DEVICE

(71) Applicant: Sharp Fukuyama Laser Co., Ltd., Fukuyama City (JP)

(72) Inventors: AKINORI NOGUCHI, Fukuyama City (JP); YOSHIHIKO TANI, Fukuyama City (JP); YUHZOH TSUDA, Fukuyama City (JP)

(21) Appl. No.: 17/122,306

(22) Filed: Dec. 15, 2020

(30) Foreign Application Priority Data
Dec. 18, 2019 (JP) 2019-228599

(51) Int. Cl. H01S 5/068; H01S 5/223

(52) U.S. Cl. CPC H01S 5/06825; H01S 5/2231

(57) ABSTRACT

A semiconductor laser device comprises a substrate; a semiconductor layer of a first conductivity type on the substrate; an active layer on the semiconductor layer of the first conductivity type; a semiconductor layer of a second conductivity type on the active layer; a ridge portion in part of the semiconductor layer of the second conductivity type; a dielectric layer covering a region of the semiconductor layer of the second conductivity type other than the ridge portion; a metal layer on the dielectric layer, the metal layer being electrically coupled to the ridge portion; and a conductive member electrically connecting the metal layer to at least the region of the semiconductor layer of the second conductivity type other than the ridge portion.

### BACKGROUND

### 1. Field

An embodiment of the present disclosure relates to semiconductor laser devices, and in particular, to a nitride semiconductor laser device.

### CROSS-REFERENCE TO RELATED APPLICATION

The present application claims priority from Japanese Application JP2019-228599, the content of which is hereby incorporated by reference into this application.

### 2. Description of the Related Art

Research and development has been done on nitride semiconductor materials, such as gallium nitride (GaN), for short-wavelength light-emitting devices, such as semiconductor laser devices and light-emitting diodes (LEDs). In recent years, with the spread of GaN-based semiconductor laser devices in the market, there have been advances in the reduction in the size of semiconductor laser devices.

However, a reduction in the size of such a semiconductor laser device decreases the junction capacitance of the device, thereby disadvantageously decreasing the electrostatic discharge (ESD) resistance. In particular, a big issue is ESD resistance at the time of the application of a back electromotive force (reverse bias) to a semiconductor laser device due to ESD.

For example, Japanese Unexamined Patent Application Publication No. 2011-199006 discloses a nitride semiconductor laser device 500 having improved ESD resistance. FIG. 16 is a cross-sectional view of the nitride semiconductor laser device 500 disclosed in Japanese Unexamined Patent Application Publication No. 2011-199006. As illustrated in FIG. 16, in the nitride semiconductor laser device 500 disclosed in Japanese Unexamined Patent Application Publication No. 2011-199006, a recessed portion 540 is arranged in part of a semiconductor layer 520b of a second conductivity type (p-type semiconductor layer), and a resistive material layer 550 is disposed in the recessed portion 540. In other words, a metal layer (p-side electrode) 532 is electrically coupled to a semiconductor layer 520a of a first conductivity type (n-type semiconductor layer) via the resistive material layer 550. This structure enables a current to flow through the semiconductor layer 520a of a first conductivity type and the metal layer 532 via the resistive material layer 550 at the time of the application of a high back electromotive force due to ESD or the like and thus can protect a ridge portion 529 from ESD.

### SUMMARY

According to an embodiment of the present disclosure, it is desirable to improve ESD resistance by the use of a structure different from the structure disclosed in Japanese Unexamined Patent Application Publication No. 2011-199006.

According to an aspect of the disclosure, there is provided a semiconductor laser device including a substrate, a semiconductor layer of a first conductivity type on the substrate, an active layer on the semiconductor layer of the first conductivity type, a semiconductor layer of a second conductivity type on the active layer, a ridge portion in part of the semiconductor layer of the second conductivity type, a dielectric layer covering a region of the semiconductor layer of the second conductivity type other than the ridge portion, a metal layer on the dielectric layer, the metal layer being electrically coupled to the ridge portion, and a conductive member electrically connecting the metal layer to at least the region of the semiconductor layer of the second conductivity type other than the ridge portion.

### BRIEF DESCRIPTION OF THE DRAWINGS

FIG. 1 is a schematic cross-sectional view of the structure of a semiconductor laser device according to a first embodiment of the present disclosure;

FIG. 2 is a top view of the semiconductor laser device according to the first embodiment of the present disclosure;

FIGS. 3A and 3B illustrate the formation pattern of the conductive member of the semiconductor laser device according to the first embodiment of the present disclosure, FIG. 3A is an enlarged top view of a region R illustrated in FIG. 2, and FIG. 3B is a schematic cross-sectional view taken along arrows IIIB-IIIB in FIG. 3A and illustrates a case where the region of a dielectric layer stacked is different from that in FIG. 1;

FIG. 4 is a flow chart of an example of a production process of the semiconductor laser device according to the first embodiment of the present disclosure;

FIG. 5 is a flow chart of another example of a production process of the semiconductor laser device according to the first embodiment of the present disclosure;

FIGS. 6A and 6B illustrate the formation pattern of the conductive member of a semiconductor laser device according to a second embodiment of the present disclosure, FIG. 6A is an enlarged top view of the region R illustrated in FIG. 2, and FIG. 6B is a schematic cross-sectional view taken along arrows VIB-VIB in FIG. 6A;

FIGS. 7A to 7C illustrate the formation pattern of conductive members of a semiconductor laser device according to a third embodiment of the present disclosure, FIG. 7A is an enlarged top view of the region R illustrated in FIG. 2, FIG. 7B is a schematic cross-sectional view taken along arrows VIIB-VIIB in FIG. 7A, and FIG. 7C is a schematic cross-sectional view taken along arrows VIIC-VIIC in FIG. 7A;

FIGS. 8A and 8B illustrate the formation pattern of the conductive member of a semiconductor laser device according to a fourth embodiment of the present disclosure. FIG. 8A is an enlarged top view of the region R illustrated in FIG. 2, and FIG. 8B is a schematic cross-sectional view taken along arrows VIIIB-VIIIB in FIG. 8A;

FIGS. 9A and 9B illustrate the formation pattern of the conductive member of a semiconductor laser device according to a fifth embodiment of the present disclosure, FIG. 9A is an enlarged top view of the region R illustrated in FIG. 2, and FIG. 9B is a schematic cross-sectional view taken along arrows IXB-IXB in FIG. 9A;

FIGS. 10A and 10B illustrate the formation pattern of the conductive member of a semiconductor laser device according to a sixth embodiment of the present disclosure, FIG. 10A is an enlarged top view of the region R illustrated in FIG. 2, and FIG. 10B is a schematic cross-sectional view taken along arrows XB-XB in FIG. 10A;

FIGS. 11A to 11C illustrate the formation pattern of the conductive member of a semiconductor laser device according to a seventh embodiment of the present disclosure, FIG. 11A is an enlarged top view of the region R illustrated in FIG. 2, FIG. 11B is a schematic cross-sectional view taken along arrows XIB-XIB in FIG. 11A, and FIG. 11C is a schematic cross-sectional view taken along arrows XIC-XIC in FIG. 11A;

FIGS. 12A to 12C illustrate the formation pattern of conductive members of a semiconductor laser device according to an eighth embodiment of the present disclosure, FIG. 12A is an enlarged top view of the region R illustrated in FIG. 2, FIG. 12B is a schematic cross-sectional view taken along arrows XIIB-XIIB in FIG. 12A, and FIG. 12C is a schematic cross-sectional view taken along arrows XIIC-XIIC in FIG. 12A;

FIGS. 13A to 13D illustrate the formation pattern of the conductive member of a semiconductor laser device according to a ninth embodiment of the present disclosure, FIG. 13A is an enlarged top view of the region R illustrated in FIG. 2, FIG. 13B is a schematic cross-sectional view taken along arrows XIIIB-XIIIB in FIG. 13A, FIG. 13C is a schematic cross-sectional view taken along arrows XIIIC-XIIIC in FIG. 13A, and FIG. 13D is a schematic cross-sectional view taken along arrows XIIID-XIIID in FIG. 13A;

FIG. 14 is a graph illustrating the results of a test for evaluation of ESD resistance;

FIG. 15 is a schematic cross-sectional view of the ridge portion and its periphery of a semiconductor laser device according to a comparative example; and

FIG. 16 is a cross-sectional view of a nitride semiconductor laser device disclosed in Japanese Unexamined Patent Application Publication No. 2011-199006.

### DESCRIPTION OF THE EMBODIMENTS

### First Embodiment

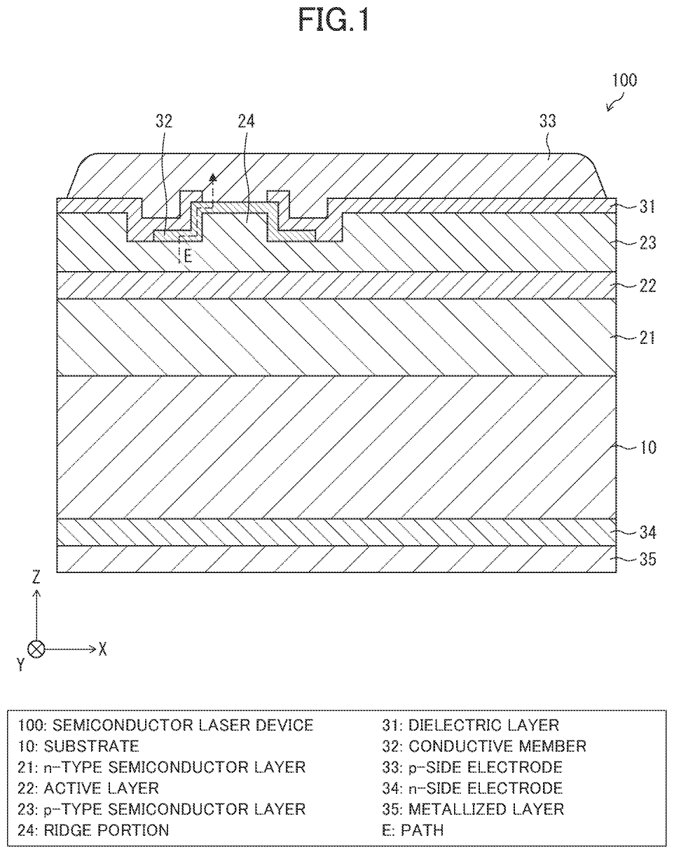

A first embodiment of the present disclosure will be described in detail with reference to FIGS. 1 to 3B.

### Structure of Nitride Semiconductor Laser Device

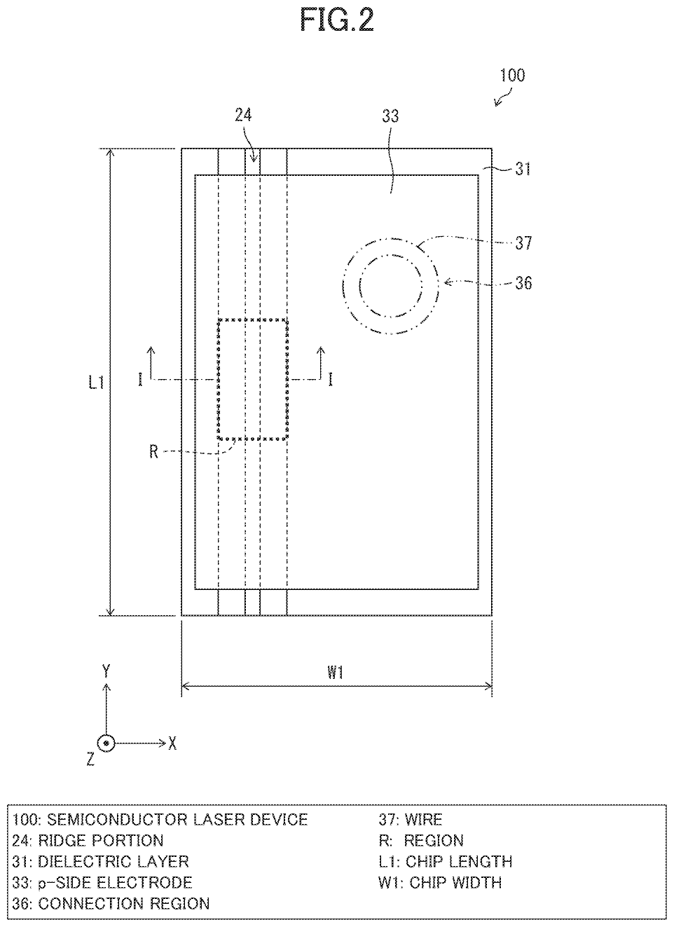

FIG. 1 is a cross-sectional view of the structure of a semiconductor laser device 100 according to this embodiment. FIG. 2 is a plan view of the semiconductor laser device 100 according to this embodiment when viewed from above. In the present specification, a nitride semiconductor laser device will be described as an example of the semiconductor laser device 100. “A to B” used in the present specification refers to “A or more and B or less”.

As illustrated in FIG. 1, the semiconductor laser device 100 includes a substrate 10, an n-type semiconductor layer (a semiconductor layer of a first conductivity type) 21, an active layer 22, a p-type semiconductor layer (a semiconductor layer of a second conductivity type) 23, a ridge portion 24, a dielectric layer 31, a conductive member 32, and a p-side electrode (metal layer) 33.

As illustrated in FIG. 1, the semiconductor laser device 100 further includes an n-side electrode 34 that is disposed on the lower side of the substrate 10 and that is configured to inject carriers from the lower side of the substrate 10, and a metallized layer 35 that is disposed on the lower side of the n-side electrode 34 and that is configured to facilitate mounting, for example, on a submount.

FIG. 1 schematically illustrates the structure of the semiconductor laser device 100 according to the embodiment. The numbers and dimensions of components included in the semiconductor laser device 100 are not limited. Regarding the coordinate axes illustrated in FIG. 1, the positive Z direction is defined as an “upper direction”, and the surface of each component in the positive z-axis direction refers to an “upper surface”.

The substrate 10 is a conductive nitride semiconductor substrate composed of, for example, GaN.

The n-type semiconductor layer 21 includes a layer composed of a semiconductor material containing free electrons serving as carriers that carry charges. The n-type semiconductor layer 21 is an example of a semiconductor layer of a first conductivity type disposed on the substrate 10. The n-type semiconductor layer 21 has a structure in which, for example, an n-type GaN layer, a lower cladding layer composed of an n-type Al_{0.1}Ga_{0.9}N, and a lower light-guiding layer composed of an n-type GaN are stacked in that order from the bottom. The n-type semiconductor layer 21 may partially include a non-n-type layer. For example, the lower light-guiding layer may be intentionally a non-doped layer in order to avoid light absorption by free electrons.

The active layer 22 is an active portion having an optical amplification effect due to stimulated emission and is disposed on the n-type semiconductor layer 21. The active layer 22 has a multiple-quantum well (MQW) structure in which, for example, multiple (for example, four) barrier layers composed of In_{0.01}Ga_{0.99} and multiple (for example, three) well layers composed of In_{0.1}Ga_{0.9}N are alternately stacked.

The p-type semiconductor layer 23 includes a layer composed of a semiconductor material containing holes serving as carriers that carry charges. The p-type semiconductor layer 23 is an example of a semiconductor layer of a second conductivity type disposed on the active layer 22. The p-type semiconductor layer 23 has a structure in which, for example, an upper light-guiding layer composed of p-type GaN, a carrier-blocking layer composed of p-type Al_{0.3}Ga_{0.7}N, an upper cladding layer composed of p-type Al_{0.1}Ga_{0.9}N, and a contact layer composed of p-type GaN are stacked in that order from the bottom. The p-type semiconductor layer 23 may partially include a non-p-type layer. For example, the upper light-guiding layer may be intentionally a non-doped layer in order to avoid light absorption by holes.

The ridge portion 24 is a portion of the p-type semiconductor layer 23 that achieves laser oscillation in a region of the active layer 22 corresponding to the portion by limiting a region through which a current flows to the Y direction. The region of the active layer 22 where the laser oscillation occurs is an optical waveguide. As illustrated in FIG. 1, the ridge portion 24 is a substantially ridge-shaped portion of the p-type semiconductor layer 23. As illustrated in FIG. 2, the ridge portion 24 extends in the Y direction.

The dielectric layer 31 functions as a current confinement layer and covers a region of the p-type semiconductor layer 23 other than the ridge portion 24. The dielectric layer 31 is composed of, for example, SiO₂.

The p-side electrode 33 is configured to inject carriers from the upper surface of the ridge portion 24 and is an example of a metal layer disposed on the dielectric layer 31. The p-side electrode 33 is electrically coupled to the top of the ridge portion 24.

The conductive member 32 electrically connects the p-type semiconductor layer 23 to the p-side electrode 33. More specifically, the conductive member 32 electrically connects the p-side electrode 33 to at least a region of the p-type semiconductor layer 23 other than the ridge portion 24 to provide a protection circuit. The conductive member 32 may be composed of, for example, a transparent conductive oxide. Examples of the transparent conductive oxide include indium tin oxide (ITO), zinc oxide (ZnO), tin oxide (SnO₂), zinc oxide-based oxide (IZO), and magnesium oxide (MgO). The effect of the conductive member 32 will be described in more detail below.

In this embodiment, as illustrated in FIG. 2, a connection region 36 to be connected to a wire 37 for supplying a current is disposed on a surface of the p-side electrode 33.

The semiconductor laser device 100 according to the embodiment has a length L1 (chip length L1) of, for example, about 1,500 μm or less (for example, about 1,200 μm) in the Y direction. The semiconductor laser device 100 has a width W1 (chip width W1) of about 100 μm to about 600 μm (for example, about 150 μm) in the X direction.

In the semiconductor laser device 100 having the dimensions described above, the n-type semiconductor layer 21 includes, for example, the n-type GaN layer having a thickness of about 3 μm, the lower cladding layer having a thickness of about 0.5 μm, and the lower light-guiding layer having a thickness of about 0.1 μm. The active layer 22 has a structure in which, for example, four barrier layers each having a thickness of about 8 nm and three well layers each having a thickness of about 4 nm are alternately stacked. The p-type semiconductor layer 23 includes, for example, the upper light-guiding layer having a thickness of about 0.1 μm, the carrier-blocking layer having a thickness of about 20 nm, the upper cladding layer having a thickness of about 0.4 μm, and the contact layer having a thickness of about 0.1 μm. The ridge portion 24 is a substantially ridge-shaped portion including, for example, the contact layer and the upper cladding layer and has a width of about 1 μm to about 50 μm (for example, about 30 μm). The dielectric layer 31 has a thickness of, for example, about 0.1 μm to about 0.3 μm (for example, about 0.15 μm). The conductive member 32 has a thickness of, for example, about 100 μm to about 700 μm (for example, 300 μm). In this specification, the “thickness” of a layer or member is the length thereof in the Z direction.

### Conductive Member 32

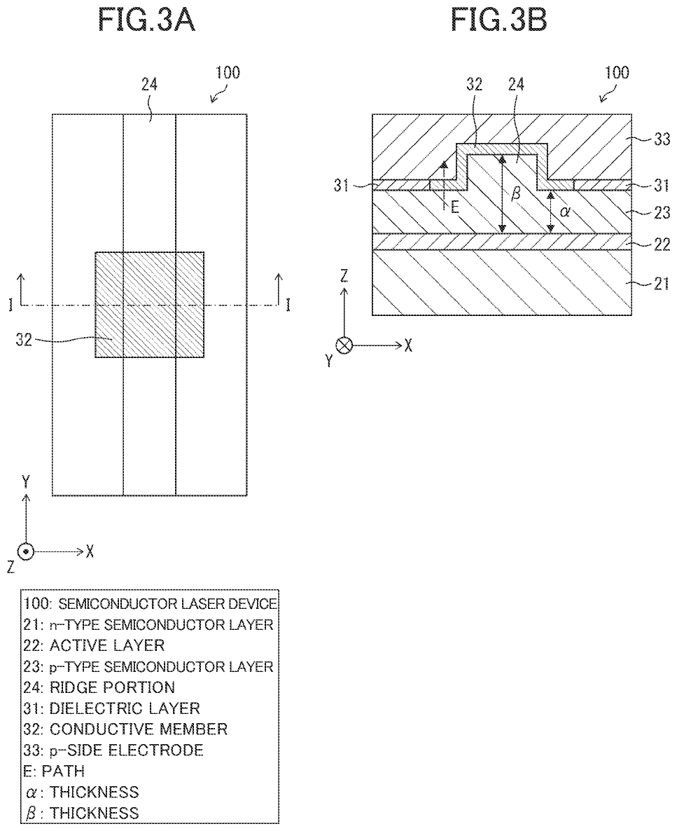

The conductive member 32 of the semiconductor laser device 100 according to the embodiment will be described in detail with reference to FIGS. 1, 3A, and 3B.

FIGS. 3A and 3B illustrate the formation pattern of the conductive member 32 of the semiconductor laser device 100 according to the embodiment. FIG. 3A is an enlarged top view of a region R illustrated in FIG. 2. In FIG. 3A, the p-side electrode 33 and the dielectric layer 31 are not illustrated in order to clearly indicate the formation pattern of the conductive member 32. The same applies to the enlarged top view of the region R in another embodiment. FIG. 3B is a schematic cross-sectional view taken along arrows IIIB-IIIB in FIG. 3A and illustrates a case where the region of the dielectric layer 31 stacked is different from that in FIG. 1.

As illustrated in FIG. 3A, the conductive member 32 extends from a region other than the ridge portion 24 to at least part of the top of the ridge portion 24. The lower surface of the conductive member 32 is in contact with the p-type semiconductor layer 23. As illustrated in FIGS. 1, 3A, and 3B, at least part of the upper surface of the conductive member 32 is in contact with the p-side electrode 33. A portion of the conductive member 32 on at least the top of the ridge portion 24 is in contact with the p-side electrode 33. That is, a portion of the conductive member 32 other than a portion of the conductive member 32 on the top of the ridge portion 24 may be or may not be covered with the dielectric layer 31. FIG. 1 is a cross-sectional view of the semiconductor laser device 100 when the portion of the conductive member 32 other than the portion of the conductive member 32 on the top of the ridge portion 24 is covered with the dielectric layer 31, in other words, when part of the upper surface of the conductive member 32 is in contact with the p-side electrode 33. FIG. 3B is a cross-sectional view of the semiconductor laser device 100 when the portion of the conductive member 32 on the top of the ridge portion 24 is not covered with the dielectric layer 31, in other words, when the entire upper surface of the conductive member 32 is in contact with the p-side electrode 33. The portion of the conductive member 32 on the top of the ridge portion 24 can act as an ohmic electrode when a forward electromotive force is applied to the semiconductor laser device 100.

As described above, the semiconductor laser device 100 includes the substrate 10, the n-type semiconductor layer 21 on the substrate 10, the active layer 22 on the n-type semiconductor layer 21, the p-type semiconductor layer 23 on the active layer 22, the ridge portion 24 on part of the p-type semiconductor layer 23, the dielectric layer 31 covering the region of the p-type semiconductor layer 23 other than the ridge portion 24, the p-side electrode 33 on the dielectric layer 31 and electrically coupled to the ridge portion 24, and the conductive member 32 electrically connecting the p-side electrode 33 to at least the region of the p-type semiconductor layer 23 other than the ridge portion 24.

In the structure described above, the conductive member 32 can provide a protection circuit capable of allowing a current to flow through a portion other than the ridge portion 24 (a path E indicated by a dashed arrow in each of FIGS. 1 and 3) between the p-type semiconductor layer 23 and the p-side electrode 33. When a high back electromotive force is applied to the semiconductor laser device 100 by, for example, ESD, the protection circuit can allow a current generated by the back electromotive force to flow from a portion of the p-type semiconductor layer 23 other than the ridge portion 24 to the p-side electrode 33 through the conductive member 32. This can protect the ridge portion 24 and the waveguide, which is formed by the ridge portion 24, in the active layer 22 directly below the ridge portion 24. That is, this can reduce the possibility of damage to the semiconductor laser device 100 by ESD. In other words, this can improve the ESD resistance of the semiconductor laser device 100.

As described above, in the semiconductor laser device 100, the conductive member 32 may extend from the region other than the ridge portion 24 to at least part of the top of the ridge portion 24.

In the above structure, the semiconductor laser device 100 can provide a protection circuit while avoiding the ridge portion 24. This can result in an improvement in ESD resistance.

The possibility that the protection circuit acts as a leak path may be reduced when a forward electromotive force is applied to the semiconductor laser device 100. In the case where the conductive member 32 is composed of a transparent conductive oxide, such as ITO, a current flows easily in the direction perpendicular to the conductive member 32 (Z direction) and does not flow easily in the direction parallel to the conductive member 32 (direction in the X-Y plane). The structure illustrated in FIG. 1 uses this property. That is, when a forward electromotive force is applied, a current flows vertically from the p-side electrode 33 toward the p-type semiconductor layer 23 through the portion of the conductive member 32 on the top of the ridge portion 24. Due to the above property, there is almost no current flowing in the direction opposite to the arrow indicating the path E illustrated in FIG. 1. The portion of the conductive member 32 other than the portion of the conductive member 32 on the top of the ridge portion 24 is closer to the active layer 22 than the portion of the conductive member 32 on the top of the ridge portion 24 (as illustrated in FIG. 3B, α<β). Thus, when a back electromotive force is applied, a current flows in the direction of the arrow indicating the path E. In other words, a protection circuit is provided in the region other than the ridge portion 24. This protects the optical waveguide in the active layer 22 directly below the ridge portion 24 from being damaged by the back electromotive force.

As illustrated in FIGS. 3A and 3B, when the dielectric layer 31 does not cover the portion of the conductive member 32 on the top of the ridge portion 24, in other words, when the entire upper surface of the conductive member 32 is in contact with the lower surface of the p-side electrode 33, the conductive member 32 possibly acts as a leak path because of the foregoing property. In this case, for example, the concentration of an impurity, such as Mg, in the upper surface region of the p-type semiconductor layer 23 other than the ridge portion 24 is set to be lower than the concentration of the impurity in the upper surface region of the ridge portion 24. Specifically, in the semiconductor laser device 100, the p-type semiconductor layer 23 contains Mg, the conductive member 32 is disposed on at least a region other than the ridge portion 24, and the interface portion (surface portion) of the p-type semiconductor layer 23 in contact with the conductive member 32 in the region other than the ridge portion 24 has a Mg concentration of about 1×10¹⁹ cm⁻³ or less. In the region other than the ridge portion 24, the contact resistance at the contact interface between the p-type semiconductor layer 23 and the conductive member 32 is increased; thus, when a forward electromotive force is applied, a current is less likely to flow. In other words, in the case of FIGS. 3A and 3B, when a forward electromotive force is applied, this structure can reduce the possibility of allowing a current to flow through a portion of the conductive member 32 disposed in the region other than the ridge portion 24 (the portion of the conductive member 32 on the sides of the ridge). This can reduce the possibility that the protection circuit formed of the conductive member 32 acts as a leak path.

As another example of a method for reducing the possibility that the protection circuit acts as a leak path, the interface portion of the p-type semiconductor layer 23, which is the contact interface between the p-type semiconductor layer 23 and the conductive member 32, may be damaged by etching. Specifically, in FIGS. 3A and 3B, the surface of the p-type semiconductor layer 23 in contact with the conductive member 32 on the sides of the ridge may be damaged by etching.

A specific method for setting the Mg concentration in the interface portion of the p-type semiconductor layer 23 to about 1×10¹⁹ cm⁻³ or less and a specific method for causing damage to the interface portion of the p-type semiconductor layer 23 by etching will be described in detail in the section of the following production method below.

In FIG. 3B, the thickness α indicates the thickness of the p-type semiconductor layer 23 in a region where a portion of the conductive member 32 other than a portion of the conductive member 32 on the ridge portion 24 is disposed. The thickness β indicates the thickness of the p-type semiconductor layer 23 at the ridge portion 24. In the semiconductor laser device 100, the thickness α is smaller than the thickness β. In the structure described above, a depletion layer that extends at the time of the application of a back electromotive force reaches the portion of the conductive member 32 in the region other than the ridge portion 24 before the depletion layer reaches a portion of the conductive member 32 on the top of the ridge portion 24. That is, this structure can enhance the effect in which a current flowing at the time of the application of a back electromotive force due to ESD is preferentially passed through the protection circuit formed of the conductive member 32.

The thickness α of the p-type semiconductor layer 23 in the region where the portion of the conductive member 32 in the region other than the ridge portion 24 is disposed may be in the range of about 10 nm to about 300 nm. The structure described above results in a sufficiently small thickness of the p-type semiconductor layer 23 in the region where the portion of the conductive member 32 in the region other than the ridge portion 24 is disposed. This can intentionally and selectively generate a punch-through state, which is caused by the expansion of the depletion layer adjacent to the active layer 22 at the time of the application of a back electromotive force, in the region other than the ridge portion 24.

The structure in which the conductive member 32 on the sides of the ridge is in direct contact with the p-side electrode 33 as illustrated in FIGS. 3A and 3B may be used in other embodiments.

### Method for Producing Semiconductor Laser Device 100

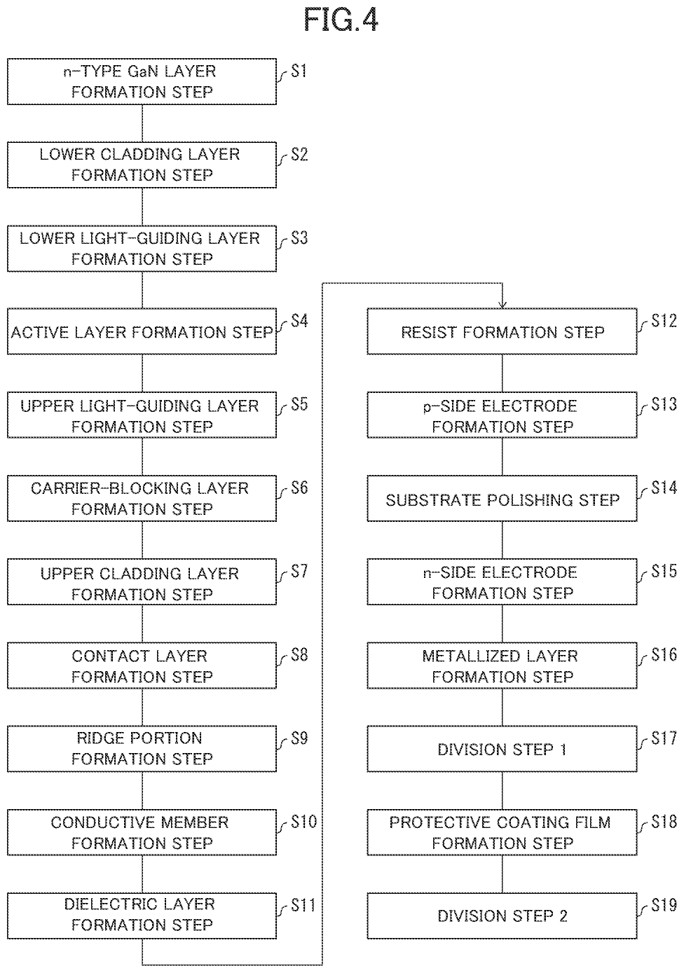

A production process of the semiconductor laser device 100 according to the embodiment will be described below with reference to FIGS. 4 and 5. FIG. 4 is a flow chart of an example of a production process of the semiconductor laser device 100 according to the embodiment. FIG. 5 is a flow chart of another example of a production process of the semiconductor laser device 100 according to the embodiment.

### Production Method 1

A production method 1 of the semiconductor laser device 100 according to the embodiment includes steps S1 to S19 as illustrated in FIG. 4. The semiconductor laser device 100 according to the embodiment is produced in this order, for example. In the embodiment, however, the order of the steps is not limited as long as the semiconductor laser device 100 having the stacked structure illustrated in FIG. 1 can be produced. The steps will be described below.

The semiconductor laser device 100 is produced, for example, with a metal-organic chemical vapor deposition (MOCVD) apparatus (not illustrated) in the steps S1 to S8. In the production, the substrate 10 is placed on a predetermined susceptor (not illustrated) in a growth chamber of the MOCVD apparatus.

In the step S1 illustrated in FIG. 4, the temperature of the susceptor in the MOCVD apparatus is increased to about 1,050° C. while N₂ and NH₃ serving as carrier gases are each flowed at a flow rate of 5 L/min. After the completion of the increase in temperature, the carrier gas is switched from N₂ to H₂. Trimethylgallium ((CH₃)₃Ga, abbreviated as “TMG”) serving as a raw material of gallium (Ga) is fed into the growth chamber at a feed rate of about 100 μmol/min. Monosilane (SiH₄) as a raw material of Si serving as an n-type dopant is fed into the growth chamber at a feed rate of about 10 nmol/min. Thereby, an n-type GaN layer having a thickness of about 3 μm is formed on the substrate 10 (n-type GaN layer formation step).

In the MOCVD apparatus in the step S2, the feed rate of TMG is reduced to about 50 μmol/min. Trimethylaluminum ((CH₃)₃Al, abbreviated as “TMA”) serving as a raw material of aluminum (Al) is fed into the growth chamber at a feed rate of about 40 μmol/min. Thereby, a lower cladding layer having a thickness of about 0.5 μm and being composed of an n-type Al_{0.1}Ga_{0.9}N is formed on the n-type GaN layer (lower cladding layer formation step).

In the MOCVD apparatus in the step S3, the feed of TMA is stopped, and the feed rate of TMG is increased to about 100 μmol/min. Thereby, a lower light-guiding layer having a thickness of about 0.1 μm and being composed of n-type GaN is formed on the lower cladding layer (lower light-guiding layer formation step). The n-type semiconductor layer 21 (the semiconductor layer of the first conductivity type) is formed through the steps S1 to S3. That is, the steps S1 to S3 can also be referred to as “n-type semiconductor layer formation steps”.

In the MOCVD apparatus in the step S4, the feed of TMG and SiH₄ is stopped, the carrier gas is switched from H₂ to N₂, and the susceptor temperature is reduced to about 700° C. Trimethylindium ((CH₃)₃In, abbreviated as “TMI”) serving as a raw material of indium (In) is fed into the growth chamber at a feed rate of about 10 μmol/min, and TMG is fed thereinto at a feed rate of about 15 μmol/min. Thereby, a barrier layer having a thickness of about 8 nm and being composed of In_{0.01}Ga_{0.99}N is grown on the lower light-guiding layer. The feed rate of TMI is increased to about 50 μmol/min to grow a well layer on the barrier layer, the well layer having a thickness of about 4 nm and being composed of In_{0.1}Ga_{0.9}N. Similarly, barrier layers and well layers are alternately grown to form the active layer 22 having a MQW structure in which four barrier layers and three well layers are stacked on the lower light-guiding layer (active layer formation step).

In the step S5, the feed of TMI is stopped, and the feed rate of TMG is increased to about 100 μmol/min. Thereby, an upper light-guiding layer having a thickness of about 0.1 μm and being composed of GaN is formed on the active layer 22 (upper light-guiding layer formation step).

In the MOCVD apparatus in the step S6, the feed of TMG is stopped, the susceptor temperature is increased to about 1,050° C., and the carrier gas is switched from N₂ to H₂. TMG is fed into the growth chamber at a feed rate of about 50 μmol/min, and TMA is fed thereinto at a feed rate of about 30 μmol/min. Bis(ethylcyclopentadienyl)magnesium ((C₂H₅C₅H₄)₂Mg, abbreviated as “EtCp₂Mg”) as a raw material of Mg serving as a p-type dopant is fed into the growth chamber at a feed rate of about 10 nmol/min. Thereby, a carrier-blocking layer having a thickness of about 20 nm and being composed of p-type Al_{0.3}Ga_{0.7}N is formed on the upper light-guiding layer (carrier-blocking layer formation step).

In the MOCVD apparatus in the step S7, the feed rate of TMG is reduced to about 50 μmol/min, and TMA is fed into the growth chamber at a feed rate of about 50 μmol/min. Bis(ethylcyclopentadienyl)magnesium ((C₂H₅C₅H₄)₂Mg, abbreviated as “EtCp₂Mg”) as a raw material of Mg serving as a p-type dopant is fed into the growth chamber at a feed rate of about 3 nmol/min. Thereby, an upper cladding layer having a thickness of about 0.4 μm and being composed of p-type Al_{0.1}Ga_{0.9}N is formed on the carrier-blocking layer (upper cladding layer formation step). The upper cladding layer has a Mg concentration of about 3×10¹⁸ cm⁻³.

In the MOCVD apparatus in the step S8, the feed rate of TMG is increased to about 100μmol/min again, and the feed of TMA is stopped. Bis(ethylcyclopentadienyl)magnesium ((C₂H₅C₅H₄)₂Mg, abbreviated as “EtCp₂Mg”) as a raw material of Mg serving as a p-type dopant is fed into the growth chamber at a feed rate of about 250 nmol/min. Thereby, a contact layer having a thickness of about 0.1 μm and being composed of p-type GaN is formed on the upper cladding layer. The contact layer has a Mg concentration of about 2×10²⁰ cm⁻³. The feed of TMG and EtCp₂Mg is stopped, and the temperature in the growth chamber is reduced (contact layer formation step). The p-type semiconductor layer 23 (semiconductor layer of the second conductivity type) is formed through the steps S5 to S8. That is, the steps S5 to S8 can also be referred to as “p-type semiconductor layer formation steps”. A nitride semiconductor wafer in which multiple nitride semiconductor layers are stacked is formed through the steps of S1 to S8. That is, the steps S1 to S8 can also be referred to as “nitride semiconductor wafer formation step”. In the p-type semiconductor layer formation steps, the Mg concentration in the p-type semiconductor layer 23 (upper cladding layer) is about 3×10¹⁸ cm⁻³, which is lower than a Mg concentration in the contact layer of about 2×10²⁰ cm⁻³. In the interface (the interface between the upper cladding layer and conductive member 32) portion between the p-type semiconductor layer 23 and the conductive member 32 in the region other than the ridge portion 24, a Mg concentration of about 1×10¹⁹ cm⁻³ or less described above can be obtained.

An ohmic electrode composed of Pd is formed on the contact layer, for example, by a vacuum evaporation method, as needed. The electrode is subjected to alloying at a high temperature so as to obtain an ohmic contact with the contact layer. The ohmic electrode is formed so as to have a thickness of, for example, about 5 nm or more and about 100 nm or less (for example, 15 nm).

In the step S9, selective etching is performed to an intermediate depth of the upper cladding layer by photolithography and dry etching techniques. Thereby, striped ridge portions 24 are formed, the ridge portions 24 being formed of ridged portions of the upper cladding layer and the contact layer, having a width of about 1 μm to about 50 μm (for example, about 30 μm), and extending in parallel with each other in the Y direction (ridge portion formation step). The etching performed in the step S9 damages the interface portion of the p-type semiconductor layer 23, which is the contact interface between the p-type semiconductor layer 23 and the conductive member 32. This can increase the contact resistance of the interface portion of the p-type semiconductor layer 23.

In the case where the ohmic electrode is formed between the steps S8 and S9, the ohmic electrode formed on a region other than the top of the ridge portion 24 is removed by photolithography and wet etching techniques.

In the step S10, a conductive layer having a thickness of about 300 nm and being composed of ITO is formed on the contact layer, for example, by a vacuum evaporation method. The conductive layer is processed by photolithography and dry etching techniques into the conductive members 32 each having a predetermined pattern (conductive member formation step).

In the step S11, the dielectric layer 31 having a thickness of about 0.1 μm to about 0.3 μm (for example, about 0.15 μm) and being composed of SiO₂ is formed on the upper surface of the nitride semiconductor wafer excluding the top of each ridge portion 24. Predetermined portions of the dielectric layer 31 are removed by photolithography and dry etching techniques so as to expose at least part of each of the conductive members 32 (dielectric layer formation step).

In the step 12, a resist having an opening is formed on the dielectric layer 31 by a photolithography technique (resist formation step).

In the step S13, a Ti layer (not illustrated) and a Au layer (not illustrated) are sequentially formed in the opening in that order from the nitride semiconductor wafer side, for example, by a vacuum evaporation method to form a multilayer metal film. The resist is removed by a lift-off process to form the p-side electrode 33 (p-side electrode formation step).

In the step S14, in order to easily divide the nitride semiconductor wafer, the substrate 10 is thinned to about 80 μm to about 150 μm (for example, about 100 μm) by grinding or polishing the lower surface of the substrate 10. The ground or polished surface is subjected to, for example, dry etching to adjust the surface (substrate polishing step).

In the step S15, a Ti layer (not illustrated) and an Al layer (not illustrated) are sequentially formed on the ground or polished lower surface of the substrate 10 from the lower surface side of the substrate 10, for example, by a vacuum evaporation method to form the n-side electrode 34 having a multilayer structure. The electrode is subjected to alloying at a high temperature so as to obtain an ohmic contact with the substrate 10 (n-side electrode formation step).

In the step S16, a Mo layer (not illustrated), a Pt layer (not illustrated), and a Au layer (not illustrated) are sequentially formed on the n-side electrode 34 from the n-side electrode 34 side to form the metallized layer 35 having a multilayer structure (metallized layer formation step).

In the step S17, the nitride semiconductor wafer formed as described above is divided (cleaved) into bars with a scribing machine in such a manner that the chip length L1 in the Y direction is, for example, about 1,200 μm (division step 1).

In the step S18, protective coating films composed of an insulating material are formed on the respective end faces of each bar divided in the division step 1 by, for example, an evaporation method or a sputtering method.

In the step S19, the bar divided in the division step 1 is divided into individual semiconductor laser devices (division step 2).

As described above, the semiconductor laser device 100 according to an embodiment of the present disclosure as illustrated in FIG. 1 is produced.

### Production Method 2

As illustrated in FIG. 5, a production method 2, which is another method for producing the semiconductor laser device 100 according to the embodiment, includes, for example, steps S1 to S19. In this embodiment, the production of the semiconductor laser device 100 is performed in this order as an example.

The production method 1 and the production method 2 are identical, except that the order of the conductive member formation step (S10) and the dielectric layer formation step (S11) is reversed.

In the step S10 of the production step 2, the dielectric layer 31 having a thickness of about 0.1 μm to about 0.3 μm (for example, about 0.15 μm) and being composed of SiO₂ is formed on the upper surface of the nitride semiconductor wafer excluding the top of each ridge portion 24. Portions of the dielectric layer 31 where the conductive members 32 are to be formed are removed by photolithography and dry etching techniques (dielectric layer formation step).

In the step S11, conductive layers each having a thickness of about 150 nm and being composed of ITO are formed, for example, by sputtering on portions of the contact layer where the portions of the dielectric layer 31 have been removed in the step S10 (conductive member formation step).

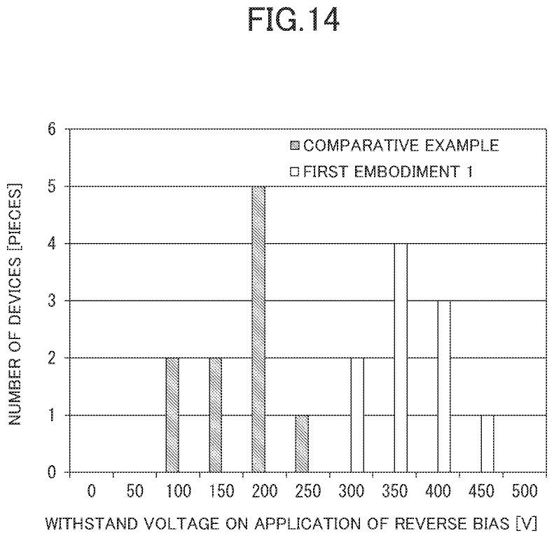

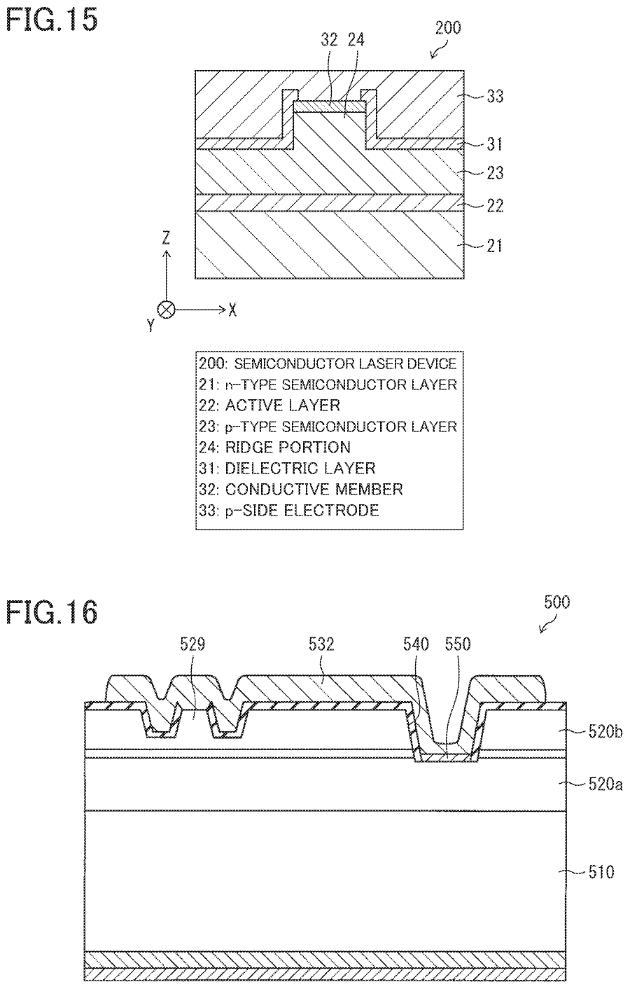

The structure and the production method of the semiconductor laser device 100 according to the first embodiment have been described above. An experiment conducted to examine the effect of the semiconductor laser device 100 according to the first embodiment will be described below with reference to FIGS. 14 and 15.

### Demonstration Experiment

### Test for Evaluation of ESD Resistance

In this experiment, the semiconductor laser device 100 (see FIG. 1) produced by the production method 1 was used as an example. A semiconductor laser device 200 illustrated in FIG. 15 was used as a comparative example. FIG. 15 is a cross-sectional view of and around the ridge portion 24 of the semiconductor laser device 200. The semiconductor laser device 200 is different from the semiconductor laser device 100 in that the conductive member 32 is disposed only on the top of the ridge portion 24 and electrically connected to the p-side electrode 33. In this demonstration experiment, the conductive member 32 of each of the semiconductor laser device 100 and the semiconductor laser device 200 was composed of ITO.

The ESD resistance of each of the semiconductor laser devices 100 and 200 at the time of the application of a back electromotive force was evaluated. The test for evaluation of ESD resistance was performed in the machine model (MM). Ten semiconductor laser devices 100 and 10 semiconductor laser devices 200 were prepared. The withstand voltage of each of the semiconductor laser devices on application of a reverse bias was measured.

FIG. 14 is a graph illustrating the results of the test for evaluation of ESD resistance. The horizontal axis of the graph illustrated in FIG. 14 indicates the withstand voltage on application of a reverse bias (V). The vertical axis of the graph illustrated in FIG. 14 indicates the number of semiconductor laser devices (pieces) at each withstand voltage level.

As illustrated in FIG. 14, each of the semiconductor laser devices 200 had a withstand voltage of 250 V or less. In contrast, each of the semiconductor laser devices 100 had a withstand voltage of 300 V or more. In the test for evaluation of ESD resistance, the average withstand voltage of the semiconductor laser devices 200 on application of a reverse bias was 150 V, and the average withstand voltage of the semiconductor laser devices 100 on application of a reverse bias was 340 V. The results demonstrated that the semiconductor laser device 100 of the example has higher reverse-bias resistance than the semiconductor laser device 200 of the comparative example. In the case where the conductive member 32 illustrated in FIG. 15 is composed of a metal, such as Ni, Pt, Au, or Pd, the withstand voltage on application of a reverse bias was 50 V or less in most cases.

Semiconductor laser devices according to other embodiments having different patterns of conductive members will be described below.

### Second Embodiment

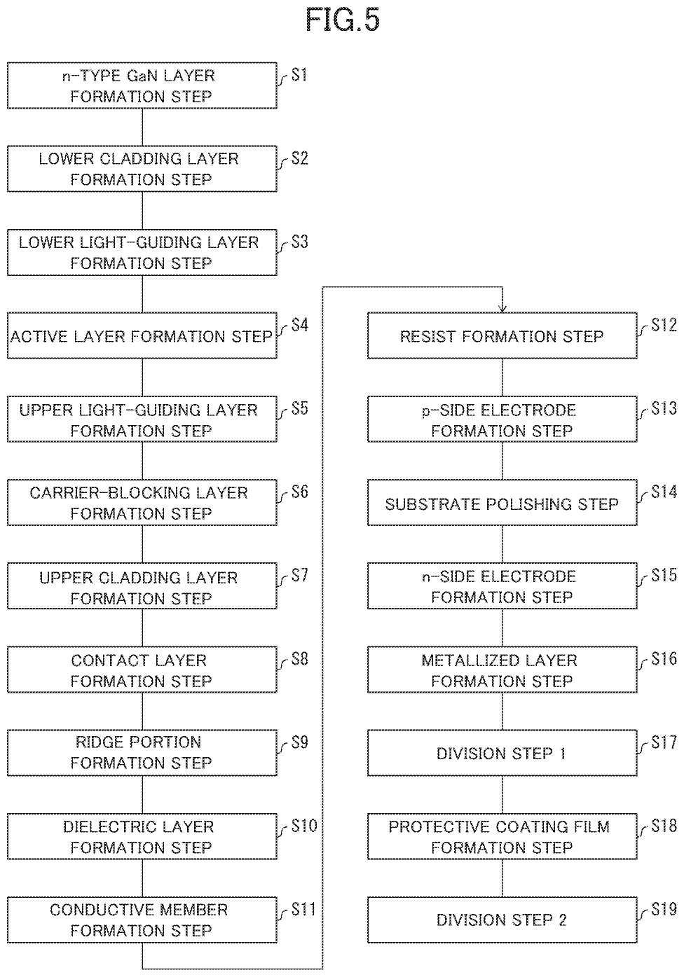

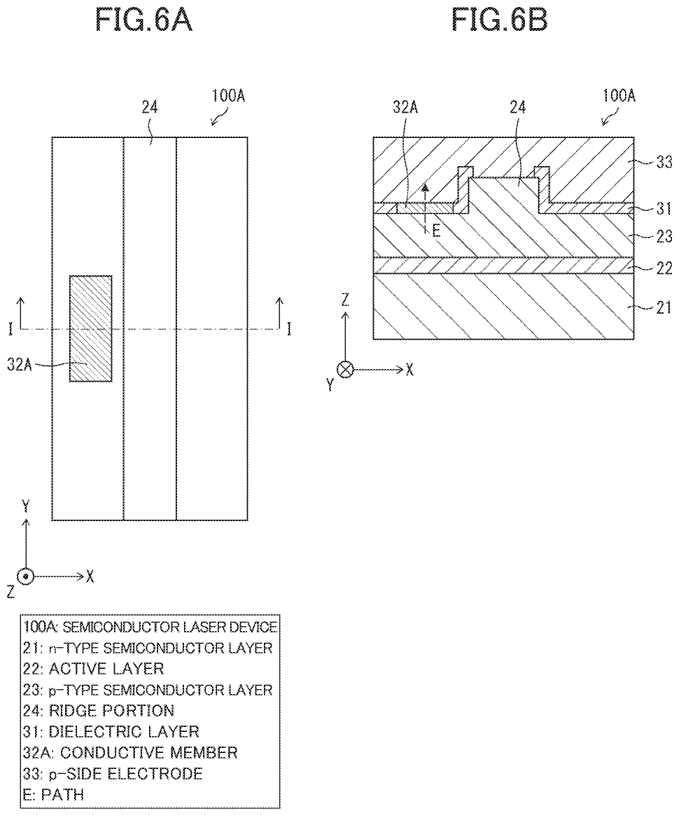

A second embodiment of the present disclosure will be described below with reference to FIGS. 6A and 6B. FIGS. 6A and 6B illustrate the formation pattern of a conductive member 32A of a semiconductor laser device 100A according to a second embodiment of the present disclosure. FIG. 6A is an enlarged top view of the region R illustrated in FIG. 2. FIG. 6B is a schematic cross-sectional view taken along arrows VIB-VIB in FIG. 6A. The formation pattern of the conductive member 32A of the semiconductor laser device 100A according to this embodiment is different from the formation pattern of the conductive member 32 of the semiconductor laser device 100 according to the first embodiment.

In FIGS. 6A and 6B, the conductive member 32A is disposed on a region of the p-type semiconductor layer 23 other than the ridge portion 24. In FIGS. 6A and 6B, the conductive member 32A is disposed in part of the region. The lower surface of the conductive member 32A is in contact with the p-type semiconductor layer 23. In this case, the dielectric layer 31 is disposed in such a manner that at least part of the conductive member 32A can be in contact with the p-side electrode 33. FIGS. 6A and 6B illustrate the configuration in which the entire upper surface of the conductive member 32A is in contact with the p-side electrode 33. However, part of the upper surface of the conductive member 32A may be in contact with the p-side electrode 33.

As described above, the conductive member 32A has a surface in contact with the region of the p-type semiconductor layer 23 other than the ridge portion 24 and a surface in contact with the p-side electrode 33; thus, a protection circuit can be provided while avoiding the ridge portion 24. When a high back electromotive force is applied to the semiconductor laser device 100A by, for example, ESD, the protection circuit can allow a current generated by the back electromotive force to flow from a portion of the p-type semiconductor layer 23 other than the ridge portion 24 to the p-side electrode 33 through the conductive member 32A. This can protect the ridge portion 24 and the waveguide, which is formed by the ridge portion 24, in the active layer 22 directly below the ridge portion 24. That is, this can reduce the possibility of damage to the semiconductor laser device 100A by ESD. In other words, this can improve the ESD resistance of the semiconductor laser device 100A.

The conductive member 32A is located away from the ridge portion 24 and thus can be composed of a conductive material other than the transparent conductive oxide.

FIGS. 6A and 6B schematically illustrate part of the semiconductor laser device according to the embodiment and do not limit the dimensions of the components. The lengths of the conductive member 32A in the X and Y directions can be freely selected. The conductive member 32A is not limited to being substantially rectangular in shape. The same applies to other embodiments.

### Third Embodiment

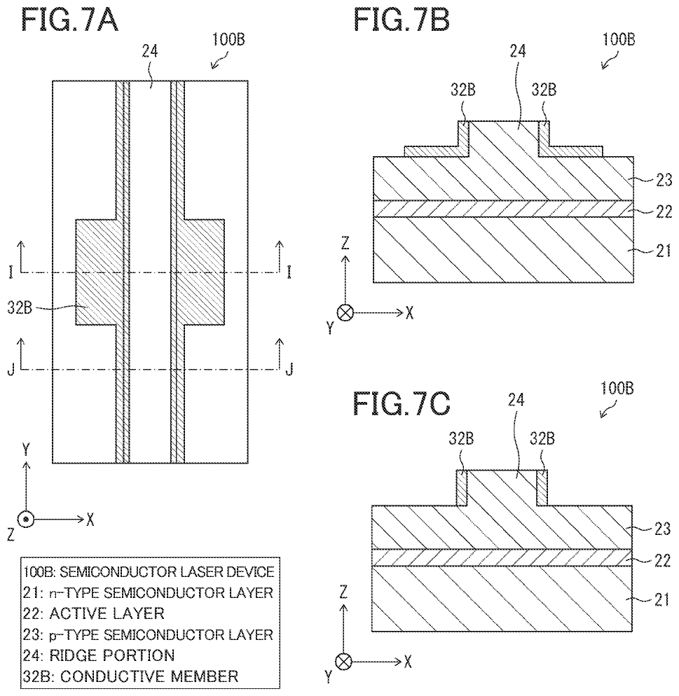

A third embodiment of the present disclosure will be described below with reference to FIGS. 7A to 7C. FIGS. 7A to 7C illustrate the formation pattern of conductive members 32B of a semiconductor laser device 100B according to the third embodiment of the present disclosure. Note that the p-side electrode 33 and the dielectric layer 31 are not illustrated. FIG. 7A is an enlarged top view of the region R illustrated in FIG. 2. FIG. 7B is a schematic cross-sectional view taken along arrows VIIB-VIIB in FIG. 7A. FIG. 7C is a schematic cross-sectional view taken along arrows VIIC-VIIC in FIG. 7A. The formation pattern of the conductive members 32B of the semiconductor laser device 100B according to this embodiment is different from the formation pattern of the conductive member 32 of the semiconductor laser device 100 according to the first embodiment.

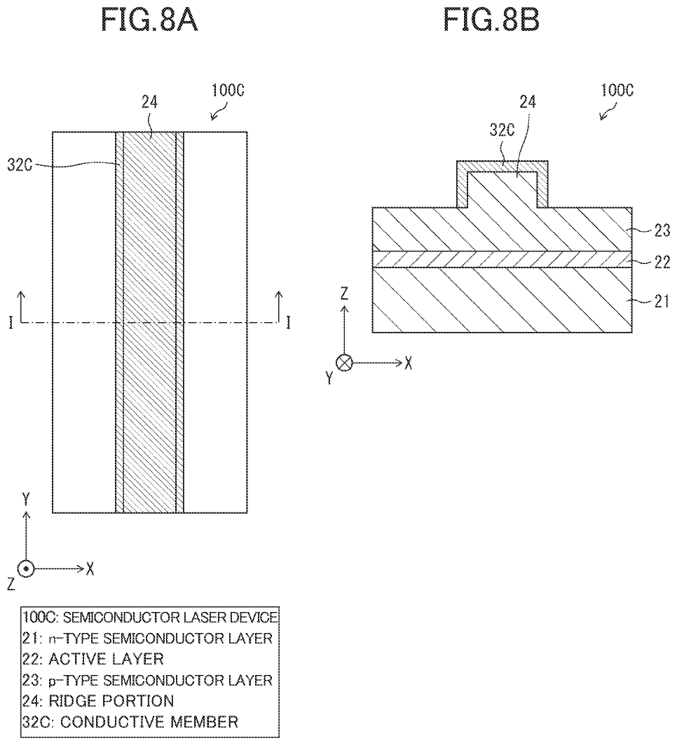

In FIGS. 7A to 7C, the conductive members 32B are disposed on regions of the p-type semiconductor layer 23 other than the ridge portion 24, the regions including the respective side faces of the ridge portion 24. In FIGS. 7A to 7C, the conductive members 32B are disposed on the respective side faces of the ridge portion 24 of the p-type semiconductor layer 23 and extend to the respective portions of the p-type semiconductor layer 23 other than the side faces of the ridge portion 24. Although the dielectric layer 31 and the p-side electrode 33 are not illustrated in FIGS. 7A to 7C, the dielectric layer 31 may be disposed in such a manner that at least part of each conductive member 32B can be in contact with the p-side electrode 33. The same applies to FIGS. 8A to 13D.

The structure described above enables the semiconductor laser device 100B according to the third embodiment to provide a protection circuit while avoiding the ridge portion 24. This can improve ESD resistance.

### Fourth Embodiment

A fourth embodiment of the present disclosure will be described below with reference to FIGS. 8A and 8B. FIGS. 8A and 8B illustrate the formation pattern of a conductive member 32C of a semiconductor laser device 100C according to the fourth embodiment of the present disclosure. Note that the p-side electrode 33 and the dielectric layer 31 are not illustrated. FIG. 8A is an enlarged top view of the region R illustrated in FIG. 2. FIG. 8B is a schematic cross-sectional view taken along arrows VIIIB-VIIIB in FIG. 8A. The formation pattern of the conductive member 32C of the semiconductor laser device 100C according to this embodiment is different from the formation pattern of the conductive member 32 of the semiconductor laser device 100 according to the first embodiment.

In FIGS. 8A and 8B, the conductive member 32C extends from the top of the ridge portion 24 to the side faces of the ridge portion 24 (on a region of the p-type semiconductor layer 23 other than the ridge portion 24). In FIGS. 8A and 8B, the conductive member 32C entirely covers the upper surface and both side faces of the ridge portion 24.

The structure described above enables the semiconductor laser device 100C according to the fourth embodiment to provide a protection circuit while avoiding the ridge portion 24. This can improve ESD resistance.

### Fifth Embodiment

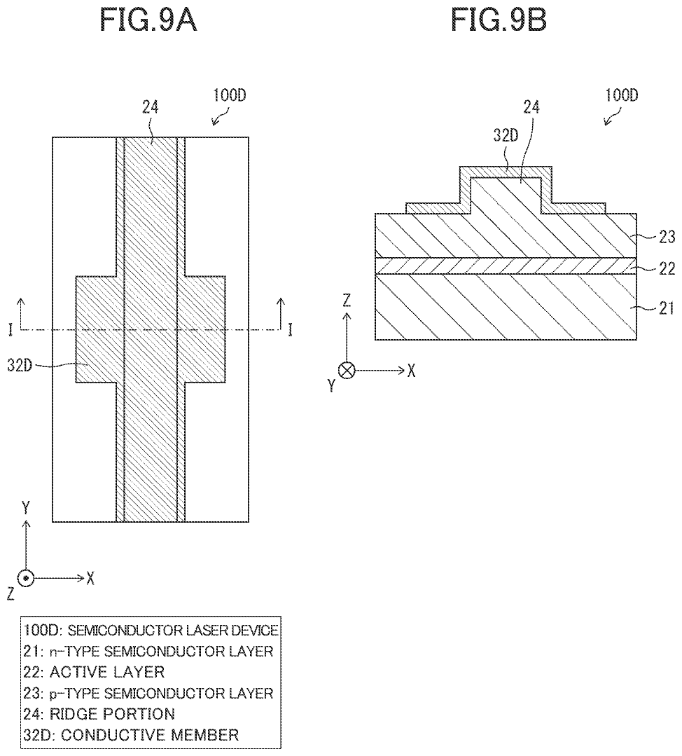

A fifth embodiment of the present disclosure will be described below with reference to FIGS. 9A and 9B. FIGS. 9A and 9B illustrate the formation pattern of a conductive member 32D of a semiconductor laser device 100D according to the fifth embodiment of the present disclosure. Note that the p-side electrode 33 and the dielectric layer 31 are not illustrated. FIG. 9A is an enlarged top view of the region R illustrated in FIG. 2. FIG. 9B is a schematic cross-sectional view taken along arrows IXB-IXB in FIG. 9A. The formation pattern of the conductive member 32D of the semiconductor laser device 100D according to this embodiment is different from the formation pattern of the conductive member 32 of the semiconductor laser device 100 according to the first embodiment.

In FIGS. 9A and 9B, the conductive member 32D extends from a region of the p-type semiconductor layer 23 other than the ridge portion 24, the region including the side faces of the ridge portion 24, to the top of the ridge portion 24. In FIGS. 9A and 9B, the conductive member 32D entirely covers the upper surface and both side faces of the ridge portion 24 and extends to a portion of the p-type semiconductor layer 23 other than the side faces of the ridge portion 24.

The structure described above enables the semiconductor laser device 100D according to the fifth embodiment to provide the protection circuit while avoiding the ridge portion 24. This can improve ESD resistance.

### Sixth Embodiment

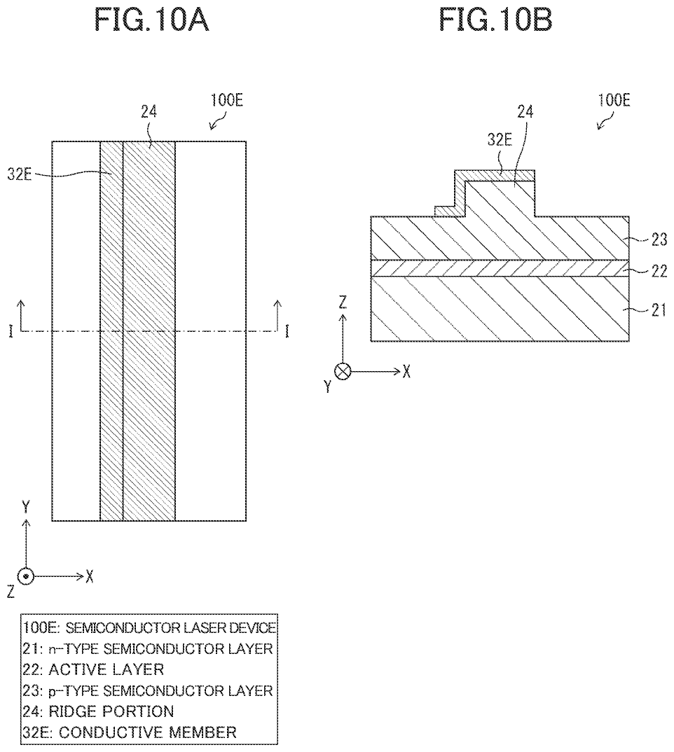

A sixth embodiment of the present disclosure will be described below with reference to FIGS. 10A and 10B. FIGS. 10A and 10B illustrate the formation pattern of a conductive member 32E of a semiconductor laser device 100E according to the sixth embodiment of the present disclosure. Note that the p-side electrode 33 and the dielectric layer 31 are not illustrated. FIG. 10A is an enlarged top view of the region R illustrated in FIG. 2. FIG. 10B is a schematic cross-sectional view taken along arrows XB-XB in FIG. 10A. The formation pattern of the conductive member 32E of the semiconductor laser device 100E according to this embodiment is different from the formation pattern of the conductive member 32 of the semiconductor laser device 100 according to the first embodiment.

In FIGS. 10A and 10B, the conductive member 32E extends from a region of the p-type semiconductor layer 23 other than the ridge portion 24, the region including one side face of the ridge portion 24, to the top of the ridge portion 24. In FIGS. 10A and 10B, the conductive member 32E covers the entire upper surface and the whole of the one side face of the ridge portion 24.

The structure described above enables the semiconductor laser device 100E according to the sixth embodiment to provide a protection circuit while avoiding the ridge portion 24. This can improve ESD resistance.

### Seventh Embodiment

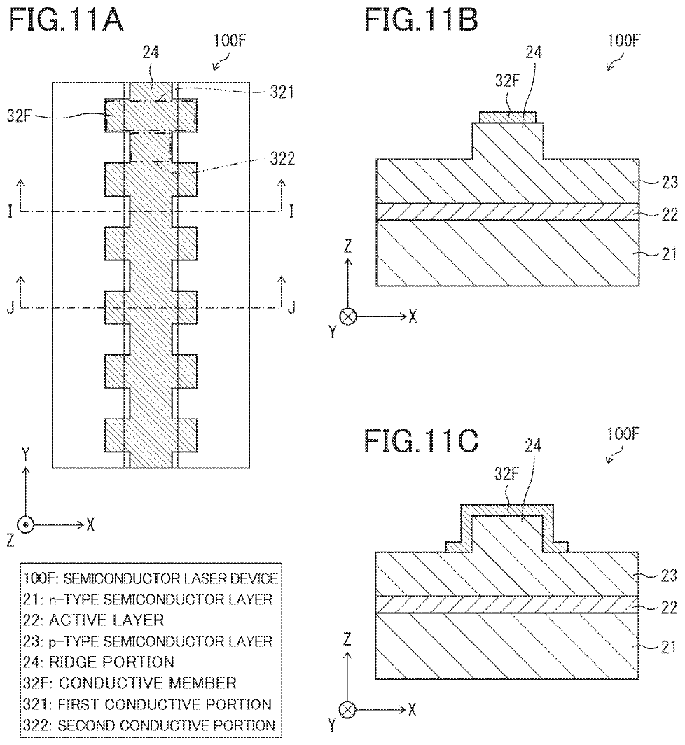

A seventh embodiment of the present disclosure will be described below with reference to FIGS. 11A to 11C. FIGS. 11A to 11C illustrate the formation pattern of a conductive member 32F of a semiconductor laser device 100F according to the seventh embodiment of the present disclosure. Note that the p-side electrode 33 and the dielectric layer 31 are not illustrated. FIG. 11A is an enlarged top view of the region R illustrated in FIG. 2. FIG. 11B is a schematic cross-sectional view taken along arrows XIB-XIB in FIG. 11A. FIG. 11C is a schematic cross-sectional view taken along arrows XIC-XIC in FIG. 11A. The formation pattern of the conductive member 32F of the semiconductor laser device 100F according to this embodiment is different from the formation pattern of the conductive member 32 of the semiconductor laser device 100 according to the first embodiment.

In FIGS. 11A to 11C, the conductive member 32F extends from a region of the p-type semiconductor layer 23 other than the ridge portion 24, the region including portions of the side faces of the ridge portion 24, to the top of the ridge portion 24. In FIGS. 11A to 11C, in portions of the upper surface of the ridge portion 24, portions of the conductive member 32F each extend from the upper surface of the ridge portion 24 to the side faces of the ridge portion 24. The portions of the conductive member 32F are referred to as “first conductive portions 321”. In portions of the upper surface of the ridge portion 24 other than the first conductive portions 321, portions of the conductive member 32F are disposed on regions other than edges in contact with the side faces of the ridge portion 24 or their vicinities. The portions of the conductive member 32F are referred to as “second conductive portions 322”. In FIGS. 11A to 11C, the first conductive portions 321 and the second conductive portions 322 are alternately arranged in the direction of extension of the ridge portion 24.

The structure described above enables the semiconductor laser device 100F according to the seventh embodiment to provide a protection circuit through the first conductive portions 321 while avoiding the ridge portion 24. This can improve ESD resistance.

### Eighth Embodiment

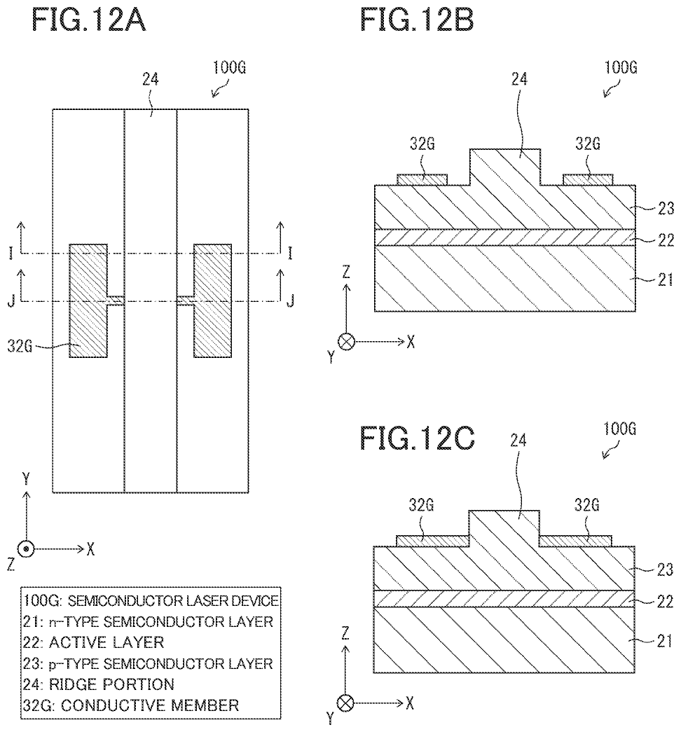

An eighth embodiment of the present disclosure will be described below with reference to FIGS. 12A to 12C. FIGS. 12A to 12C illustrate the formation pattern of conductive members 32G of a semiconductor laser device 100G according to the eighth embodiment of the present disclosure. Note that the p-side electrode 33 and the dielectric layer 31 are not illustrated. FIG. 12A is an enlarged top view of the region R illustrated in FIG. 2. FIG. 12B is a schematic cross-sectional view taken along arrows XIIB-XIIB in FIG. 12A. FIG. 12C is a schematic cross-sectional view taken along arrows XIIC-XIIC in FIG. 12A. The formation pattern of each of the conductive members 32G of the semiconductor laser device 100G according to this embodiment is different from the formation pattern of the conductive member 32 of the semiconductor laser device 100 according to the first embodiment.

In FIGS. 12A to 12C, the conductive members 32G are disposed on respective regions of the p-type semiconductor layer 23 other than the ridge portion 24, each of the regions including part of a corresponding one of the side faces of the ridge portion 24. In FIGS. 12A to 12C, each of the conductive members 32G includes a conductive portion disposed on part of a corresponding one of the regions and a conductive portion connecting the conductive portion and a corresponding one of the side faces of the ridge portion 24.

The structure described above enables the semiconductor laser device 100G according to the eighth embodiment to provide a protection circuit while avoiding the ridge portion 24. This can improve ESD resistance.

### Ninth Embodiment

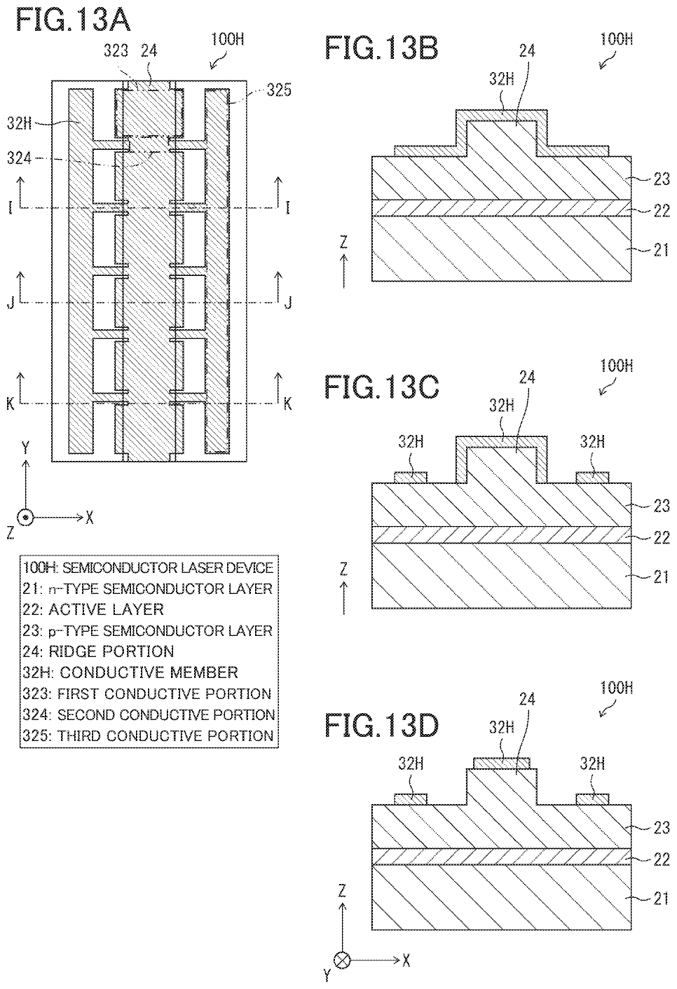

A ninth embodiment of the present disclosure will be described below with reference to FIGS. 13A to 13D. FIGS. 13A to 13D illustrate the formation pattern of a conductive member 32H of a semiconductor laser device 100H according to the ninth embodiment of the present disclosure. Note that the p-side electrode 33 and the dielectric layer 31 are not illustrated. FIG. 13A is an enlarged top view of the region R illustrated in FIG. 2. FIG. 13B is a schematic cross-sectional view taken along arrows XIIIB-XIIIB in FIG. 13A. FIG. 13C is a schematic cross-sectional view taken along arrows XIIIC-XIIIC in FIG. 13A. FIG. 13D is a schematic cross-sectional view taken along arrows XIIID-XIIID in FIG. 13A. The formation pattern of the conductive member 32H of the semiconductor laser device 100H according to this embodiment is different from the formation pattern of the conductive member 32 of the semiconductor laser device 100 according to the first embodiment.

In FIGS. 13A to 13D, the conductive member 32H is disposed on a region of the p-type semiconductor layer 23 other than the ridge portion 24 and on the top of the ridge portion 24, the region including portions of each of the side faces of the ridge portion 24. In FIGS. 13A to 13D, the conductive member 32H includes first conductive portions 323 and second conductive portions 324 alternately arranged on the ridge portion 24. The conductive member 32H also includes, on a region of the p-type semiconductor layer 23 other than the ridge portion 24, third conductive portions 325 extending in the direction of extension of the ridge portion 24 on both sides of the ridge portion 24, and conductive portions connecting the second conductive portions and the third conductive portions.

The structure described above enables the semiconductor laser device 100H according to the ninth embodiment to provide a protection circuit while avoiding the ridge portion 24. This can improve ESD resistance.

### Appendix

The present disclosure is not limited to the embodiments, but can be altered by a skilled person in the art within the scope of the claims. The present disclosure also encompasses, in its technical scope, any embodiment derived by combining technical means disclosed in differing embodiments. Further, it is possible to form a new technical feature by combining the technical means disclosed in the respective embodiments.

While there have been described what are at present considered to be certain embodiments of the invention, it will be understood that various modifications may be made thereto, and it is intended that the appended claims cover all such modifications as fall within the true spirit and scope of the invention.

The present disclosure contains subject matter related to that disclosed in Japanese Priority Patent Application JP 2019-228599 filed in the Japan Patent Office on Dec. 18, 2019, the entire contents of which are hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A semiconductor laser device, comprising:
a substrate;
a semiconductor layer of a first conductivity type on the substrate;
an active layer on the semiconductor layer of the first conductivity type;
a semiconductor layer of a second conductivity type on the active layer;
a ridge portion in part of the semiconductor layer of the second conductivity type;
a dielectric layer covering a region of the semiconductor layer of the second conductivity type other than the ridge portion;
a metal layer on the dielectric layer, the metal layer being electrically coupled to the ridge portion; and
a conductive member electrically connecting the metal layer to at least the region of the semiconductor layer of the second conductivity type other than the ridge portion.

2. The semiconductor laser device according to claim 1, wherein the conductive member is disposed on the region other than the ridge portion.

3. The semiconductor laser device according to claim 1, wherein the conductive member extends from the region other than the ridge portion to at least part of a top of the ridge portion.

4. The semiconductor laser device according to claim 1, wherein the semiconductor layer of the second conductivity type contains Mg,
the conductive member is disposed on at least the region other than the ridge portion, and
an interface portion of the semiconductor layer of the second conductivity type in contact with the conductive member in the region other than the ridge portion has a Mg concentration of 1×10¹⁹ cm⁻³ or less.

5. The semiconductor laser device according to claim 1, wherein the conductive member is disposed on at least the region other than the ridge portion, and
the semiconductor layer of the second conductivity type in an area where the conductive member is disposed in the region other than the ridge portion has a smaller thickness than the semiconductor layer of the second conductivity type at the ridge portion.

6. The semiconductor laser device according to claim 5, wherein the semiconductor layer of the second conductivity type in the area where the conductive member is disposed has a thickness of 10 nm or more and 300 nm or less.
